(19) United States
(12) Patent Application Publication
(10) Pub. No.: US 2026/0019033 A1
(43) Pub. Date: Jan. 15, 2026

(54) Systems and Methods for Suppressing Noise-Induced Phase Diffusion

(71) Applicant: The Board of Trustees of the University of Illinois, Urbana, IL (US)

(72) Inventor: Harry Jan Brickman Dankowicz, Urbana, IL (US)

(21) Appl. No.: 19/267,395

(22) Filed: Jul. 11, 2025

Related U.S. Application Data
(60) Provisional application No. 63/670,515, filed on Jul. 12, 2024.

(51) Int. Cl. H03B 1/04

(52) U.S. Cl. CPC H03B 1/04; H03B 2202/076

(57) ABSTRACT

Embodiments include a system for reducing noise-induced phase diffusion of an oscillator. The system includes a sensor, a first drive signal generator, an adaptive controller, and a second drive signal generator. The sensor is configured to generate a sensor output indicative of oscillations of an oscillator. The first drive signal generator is configured to receive the sensor output and generate, based on the sensor output, a first drive signal. The first drive signal is provided to the oscillator. The adaptive controller is configured to receive the sensor output and determine, based at least in part on the sensor output, one or more adaptive control parameters. The second drive signal generator is configured to receive the sensor output and the adaptive control parameters, and generate, based on the sensor output and the adaptive control parameters, a second drive signal. The second drive signal is provided to the oscillator.

### CROSS-REFERENCE TO RELATED APPLICATION

This application claims priority to U.S. provisional patent application No. 63/670,515, filed Jul. 12, 2024, which is hereby incorporated by reference in its entirety.

### BACKGROUND

Oscillators play a critical role in various applications, including use as timing devices such as clocks and frequency synthesizers. Timing devices are included in a wide array of electronics including cell phones, tablets, laptops, desktop computers, servers, GPS units, and other electronics. In some examples, timing devices can rely on the oscillations of a micromechanical oscillator to provide a time signal. Timing devices can be integral to the operation of processing systems of electronics, and can allow for independent measurement of time and performance of computing operations (e.g., without the need for an external reference time). However, timing devices can be susceptible to phase noise, which can impact an accuracy of a timing device. Phase noise can arise from various sources including, for example, thermal fluctuations, flicker noise, and environmental disturbances.

### SUMMARY

The embodiments herein present systems and methods for reducing a noise-induced phase diffusion for an oscillator.

In a first example embodiment, the present disclosure can provide a system reducing a noise-induced phase diffusion for an oscillator. The system can include a sensor, a first drive signal generator, an adaptive controller, and a second drive signal generator. The sensor can be configured to generate a sensor output indicative of oscillations of an oscillator. The first drive signal generator can be configured to receive the sensor output, and generate, based on the sensor output, a first drive signal. The first drive signal generator can provide the first drive signal to the oscillator. The adaptive controller can be configured to receive the sensor output, and determine, based at least in part on the sensor output, one or more adaptive control parameters. The second drive signal generator can be configured to receive the sensor output and the adaptive control parameters, and generate, based on the sensor output and the adaptive control parameters, a second drive signal. The second drive signal generator can provide the second drive signal to the oscillator.

In some examples, the oscillator comprises a microelectromechanical system (MEMS) oscillator. In some examples the first drive signal generator comprises a first hardware component, wherein the first drive signal is generated based at least in part on a preset excitation amplitude, wherein the preset excitation amplitude is based on a first physical parameter of the first hardware component. In some examples, the first drive signal is based at least in part on a preset phase shift, wherein the preset phase shift is indicative of a phase difference between the sensor output and the first drive signal, wherein the preset phase shift is based on a second physical parameter of the first hardware component. In some examples, the one or more adaptive control parameters include an adaptive excitation amplitude, wherein the second drive signal is based at least in part on the adaptive excitation amplitude. In some examples, the one or more adaptive control parameters include an adaptive phase shift, the adaptive phase shift at least partially defining a phase difference between the second drive signal and the sensor output. In some examples, the adaptive controller generates a first value for the adaptive control parameter at a first time, and the controller generates a second value for the adaptive control parameter at a second time, wherein the adaptive controller generates the second value based at least in part on the first value. In some examples, the first drive signal is described by a first oscillatory function with preset excitation amplitude S and preset phase shift Δ, wherein Δ defines a phase difference between the first drive signal and the sensor output, and the second drive signal is described by a second oscillatory function with adaptive excitation amplitude T and adaptive phase shift θ, wherein θ defines a phase difference between the second drive signal and the sensor output. In some examples, the first oscillatory function is described by the expression Scos(ωt+ϕ+Δ) and the second oscillatory function is described by expression Tcos(ωt+ϕ+θ) where ω is representative of a physical parameter of the oscillator. In some examples, an average change in ϕ over a time scale 2πω\hat{ }(−1) is less than 1. In some examples, the first drive signal generator comprises a first phase-locked loop, and wherein the second drive signal generator comprises a second phase-locked loop. In some examples, the adaptive controller comprises a microcontroller. In some examples, the adaptive controller is configured to determine the adaptive excitation amplitude T based at least in part on the preset excitation amplitude S and a preset constant.

In a second example embodiment, the present disclosure can provide a method of reducing a noise-induced phase diffusion for an oscillator. The method can include generating an output indicative of the oscillations of an oscillator and providing the output to a first drive signal generator. The method can further include generating a first drive signal at the first drive signal generator, based at least in part on the output, a preset excitation amplitude, and a preset phase difference. The method can further include providing the first drive signal to the oscillator. The method can further include providing the output to an adaptive controller. The method can further include generating, at the adaptive controller, an adaptive excitation amplitude and an adaptive phase difference, the adaptive excitation amplitude and the adaptive phase difference being generated based at least in part on the output. The method can further include providing the adaptive excitation amplitude and the adaptive phase difference to a second drive signal generator. The method can further include generating a second drive signal at the second drive signal generator, based at least in part on the output, the adaptive excitation amplitude, and the adaptive phase difference, and providing the second drive signal to the oscillator.

In some examples, the oscillator is a microelectromechanical system (MEMS) oscillator.

In a third example embodiment, the present disclosure can provide a method of reducing a noise-induced phase diffusion for an oscillator. The method can include generating, at a sensor, an output indicative of the oscillations of an oscillator, and providing the output to a first drive signal generator. The method can further include generating at the first drive signal generator, based on the sensor output, a first drive signal. The method can further include providing the first drive signal to the oscillator to drive an oscillation of the oscillator. The method can further include providing the output to an adaptive controller. The method can further include determining, at the adaptive controller, based at least in part on the sensor output, one or more adaptive control parameters. The method can further include providing the output and the one or more adaptive control parameters to a second drive signal generator. The method can further include generating, at the second drive signal generator, based on the output and the one or more adaptive control parameters, a second drive signal and providing the second drive signal to the oscillator to drive an oscillation of the oscillator.

In some examples, the first drive signal generator comprises a first hardware component, wherein the first drive signal is generated based at least in part on a preset excitation amplitude, wherein the preset excitation amplitude is based on a first physical parameter of the first hardware component. In some examples, the first drive signal is based at least in part on a preset phase shift, wherein the preset phase shift is indicative of a phase difference between the output and the first drive signal, wherein the preset phase shift is based on a second physical parameter of the first hardware component. In some examples, the one or more adaptive control parameters include an adaptive excitation amplitude, wherein the second drive signal is based at least in part on the adaptive excitation amplitude. In some examples, the one or more adaptive control parameters include an adaptive phase shift, the adaptive phase shift at least partially defining a phase difference between the second drive signal and the output

### BRIEF DESCRIPTION OF THE DRAWINGS

FIG. 1 illustrates an electronic device including a timing device according to aspects of the disclosure.

FIG. 2 illustrates a schematic of a timing device including an adaptive controller, according to aspects of the disclosure.

FIG. 3 illustrates three bar charts showing a distribution of results of numerical simulations of individual feedback designs.

FIG. 4 is a flow chart, in accordance with example embodiments.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features unless stated as such. Thus, other embodiments can be utilized and other changes can be made without departing from the scope of the subject matter presented herein.

Accordingly, the example embodiments described herein are not meant to be limiting. It will be readily understood that the aspects of the present disclosure, as generally described herein, and illustrated in the figures, can be arranged, substituted, combined, separated, and designed in a wide variety of different configurations.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

Additionally, any enumeration of elements, blocks, or steps in this specification or the claims is for purposes of clarity. Thus, such enumeration should not be interpreted to require or imply that these elements, blocks, or steps adhere to a particular arrangement or are carried out in a particular order.

### I. Overview

The present disclosure includes descriptions of systems and methods for suppressing noise-induced phase diffusion in oscillators used for timing devices (e.g., micromechanical oscillators used in cell phones and GPS unit). In some examples of the disclosed systems, feedback control can be designed and implemented in a novel and unique way to modify the natural behavior of the oscillators in a way that compensates for noise-induced variations in the properties of the mechanical and electronic components. The theoretical derivation shows that over a slow time scale and to dominant order of analysis, phase diffusion can be suppressed entirely, rendering the feedback-controlled device frequency stable to several orders of magnitude higher than without.

### II. Example Systems

Some examples of the present disclosure can provide timing devices for electronic devices. Electronic devices can rely on internal timing devices (e.g., clocks) for regulating a performance of elements of the electronic device, and for synchronizing an operation between components of the electronic device. In some examples, an internal timing device for an electronic device can include an oscillator that can oscillate (e.g., vibrate) with a periodicity, and the timing device can provide a clock signal to a processor of the electronic device based on a periodicity of the oscillations.

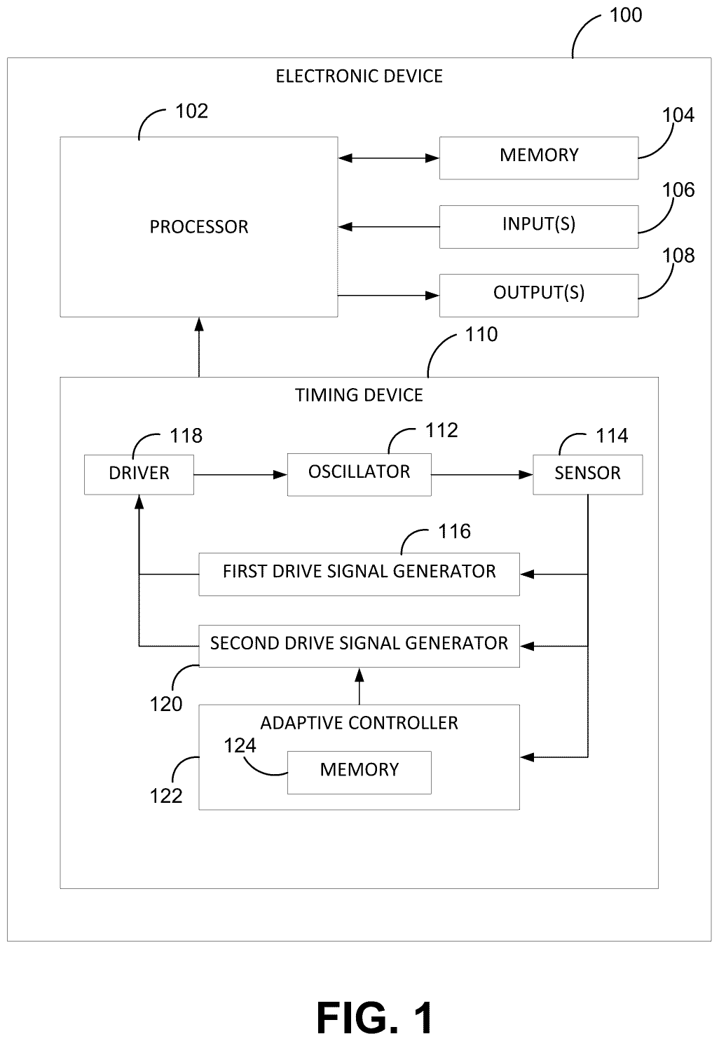

In this regard, FIG. 1 illustrates an example electronic device 100, according to some aspects of the disclosures. In some examples, the electronic device 100 can be a cell phone, a tablet, a global positioning system (GPS) device, a laptop, a computer, a server, a head-worn display, a wrist-worn electronic device, an internet-of-things (IOT) integrated device or sensor, or any other known electronic device having a processing capacity. In the illustrated example, the electronic device 100 includes a processor 102, a memory 104, one or more inputs 106, and one or more outputs 108.

The processor 102 can be any suitable hardware processor or combination of processors, such as a central processing unit (CPU), a graphics processing unit (GPU), an application specific integrated circuit (ASIC), a field-programmable gate array (FPGA), etc. In some examples, the processor 102 can be a programmable logic controller. In some embodiments, the one or more inputs 106 can comprise any element that can provide a signal from an environment or from a user to the processor. For example, the one or more inputs 106 can include a touch screen, a keyboard, a mouse, a sensor, a joystick, a limit switch, a microphone, or any other user input element. The one or more outputs 108 can include any known systems or devices for communicating an output from the processor. For example, the one or more outputs 108 can include a screen, a speaker, a light, a motor, a haptic feedback system, or any other known output for an electronic device.

In some embodiments, the memory 104 can include any suitable storage device or devices that can be used to store instructions, values, etc., that can be used, for example, by the processor 102 to implement control operation of the electronic device 100. The memory 104 can include any suitable volatile memory, non-volatile memory, storage, or any suitable combination thereof. For example, the memory can include random access memory (RAM), read-only memory (ROM), electronically-erasable programmable read-only memory (EEPROM), one or more flash drives, one or more hard disks, one or more solid state drives, one or more optical drives, etc. In some embodiments, the memory 104 can have encoded thereon a computer program for controlling operation of the electronic device 100.

As further shown in FIG. 1, the electronic device 100 includes a timing device 110 (e.g., a clock). The timing device 110 can be in communication with the processor 102 and can provide a clock signal to the processor 102 to facilitate operation of the electronic device. For example, the processor 102 can use the clock signal from the timing device to synchronize an operation of the processor 102 and the memory 104. In some examples, the clock signal from the timing device 110 can be determinative of a speed at which the processor 102 performs a sequence of actions.

As shown, the timing device 110 can include an oscillator 112. The oscillator 112 can be an element that oscillates (e.g., vibrates) periodically (e.g., in a sinusoidal waveform) and the periodic oscillations of the oscillator can be used to generate the clock signal. The clock signal provided by the timing device 110 to the processor can be based on a frequency of the oscillations of the oscillator 112. In a particular example, the oscillator 112 can be a micro-electro-mechanical system (MEMS). For example, the oscillator 112 can be a resonator including a cantilevered beam that can vibrate (e.g., in response to an excitation) at a frequency, and the clock signal can be based on the frequency of the vibration of the cantilevered beam. In some examples, an oscillator for a timing device can be a silicon MEMS oscillator, a quartz crystal oscillator, a surface acoustic wave (SAW) oscillator, and/or a voltage-controlled oscillator, etc.

In examples, a timing device (e.g., the timing device 110) can include systems for converting an oscillation of an oscillator to an electronic signal. For example, as shown, the timing device 110 includes a sensor 114. The sensor 114 can generate an electronic output signal based on sensed oscillations of the oscillator 112. The electronic output signal can have a periodicity (e.g., a frequency) that is based on the frequency of the oscillations of the oscillator. In some cases, the frequency of an electronic output signal from the sensor 114 can be identical or substantially identical to the frequency of the oscillations of the oscillator (e.g., the frequency of the electronic output signal can differ from the frequency of the oscillations of the oscillator 112 by less than 5%). In an example, the sensor 114 can be an optical sensor (e.g., a laser) that can measure changes in a light in response to oscillations of the oscillator 112 (e.g., vibrations of a cantilevered beam of the oscillator), and produce an electronic output signal based on the changes in the light (e.g., based on an interruption in a laser beam). In other examples, the sensor 112 can be a piezoelectric sensor that can generate a voltage based on a mechanical strain produced at the oscillator 112 by the oscillations. In some examples, the sensor 114 can be a piezoresistive sensor, a capacitive sensor, a Hall sensor, or any known sensor capable of producing an electronic output signal (e.g., an output voltage) based on an oscillation (e.g., a vibration) of an oscillator.

In operation, absent a drive input (e.g., an excitation signal), an energy of an oscillator can dissipate over time, which can result in a slowing of the oscillations of the oscillator (e.g., a progressive diminution of the oscillations until the oscillations cease). A change in energy of the oscillator due to dissipation can negatively impact a performance, speed, and reliability of a processor (e.g., the processor 102). In examples, a timing device can include components for countering a dissipation, and ensuring a sustained oscillation of an oscillator at a desired frequency. For example, as further shown in FIG. 1, the timing device 110 includes a first drive signal generator 116. The first drive signal generator 116 can comprise electronic components that are configured to generate a first drive signal based on the electronic output signal from the sensor 114. In an example, the frequency of the first drive signal generated by first drive signal generator 116 can mirror the frequency of the oscillations of the oscillator 112. In an example, a phase of the first drive signal can be shifted relative to the phase of the oscillations (e.g., the vibrations) of the oscillator 112. In an example, the first drive signal generator 116 can comprise a phase locked loop. The first drive signal generator 116 can generate the first drive signal based on physical properties of the electronics of the first drive signal generator 116. For example, the first drive signal generator 116 can be a phase locked loop including a phase detector, a low pass filter, a DC amplifier, and a voltage-controlled oscillator. In an example, a behavior of each of the phase detector, low pass filter, DC amplifier, and voltage-controlled oscillator can be determined by circuit elements (e.g., resistors, capacitors, inductors, etc.) of the respective component. In a particular example, the hardware of the first drive signal generator 116 (e.g., the circuit elements and other hardware) can be determinative of how the first drive signal is generated from the electronic output signal. For example, resistance values of resistors of the first drive signal generator can at least partially determine an amplitude of the first drive signal, and/or a phase shift of the drive signal relative to the electronic output signal. The first drive signal generator 116 can thus be engineered (e.g., circuitry of the first drive signal generator can be designed) to produce a preset excitation amplitude for the first drive signal (e.g., an amplitude of the first output signal) and a preset phase shift for the first drive signal, relative to any electronic signal input to the first drive signal generator. Thus, the first drive signal generator 116 can generate the first drive signal in a time invariant way, and the first drive signal can be based solely on the electronic output signal provided to the first drive signal generator 116 and the physical properties (e.g., electronic properties of circuitry) of the first drive signal generator 116. In an example, the first drive signal can be sinusoidal, or approximately sinusoidal (e.g., as described below in equations (1) and (5)). In other examples, a first drive signal can include a square wave with alternating outputs produced at steps in time.

The first drive signal from the first drive signal generator 116 can be provided to the oscillator 112 to drive an oscillation of the oscillator. The oscillation of the oscillator 112 driven by the feedback (e.g., the first drive signal) can be a self-sustained oscillation, and the first drive signal generator 116 can provide an energy to the oscillator 112 via the first drive signal to counteract the effects of a dissipation on the oscillations of the oscillator 112 (e.g., a diminution of the vibrations of the MEMS oscillator). In some examples, the first drive signal can be provided directly to the oscillator 112, and the electrical signal can drive an oscillation of the oscillator 112. In some cases, a driver 118 can be provided to translate the first drive signal into a driving input for the oscillator 112. For example, the driver 118 can drive the oscillator 112 based on an input signal (e.g., the first drive signal) using electrostatic actuation. For example, the first drive signal can be provided to electrodes of the driver 118 that are positioned near the oscillator 112, and the electrode can cause a vibration of the oscillator 112.

In some examples, as described further below, an output of an oscillator can degrade over time, which can lead to an inaccuracy of a clock signal, and corresponding performance issues for processors reliant on the clock signal. For example, an oscillator can undergo a phase diffusion, due in part to thermal fluctuations, flicker noise, and environmental disturbances. A phase diffusion can occur over a relatively slow time period, and can potentially be imperceptible over a short period of time. Conventional systems for countering a dissipation of an oscillator (e.g., a phase-locked loop to achieve self-sustaining oscillations of an oscillator) can be inadequate to counteract a phase diffusion. For example, conventional phase-locked loops (e.g., the first drive signal generator) can be time-invariant, and can fail to adjust an output drive signal to account for slowly changing parameters of an oscillation that result in a phase diffusion. Some examples of the present disclosure can reduce a phase diffusion (e.g., a noise-induced phase diffusion) for a signal by providing drive signal generators that can adapt parameters of a drive signal over time to counteract a diffusion in a signal from an oscillator (e.g., the electronic output signal). For example, as further shown, the timing device 110 can include a second drive signal generator 120 and an adaptive controller 122. The second drive signal generator 120 can receive the electronic output signal from the sensor 114, and can generate a second drive signal, based at least in part on the electronic output signal. In an example, the second drive signal generator 120 can include electronic components similar to the electronic components of the first drive signal generator 116. For example, in some embodiments, the second drive signal generator 120 includes a phase detector, a low pass filter, a DC amplifier, and a voltage-controlled oscillator. In an example, the second drive signal generator 120 comprises a second phase-locked loop. In examples, the adaptive controller 122 can be any microcontroller capable of implementing the methods described below for suppressing a phase diffusion of an oscillator. In an example, as shown, the adaptive controller includes a memory 124. The memory 124 can comprise any combination of volatile and non-volatile memory (e.g., as described with respect to memory 104), and can have stored thereon instructions and parameters for the adaptive controller to implement in order to produce, via the second drive signal generator 120, the second drive signal. In some examples, the memory 124 can store historical values (e.g., previous state values, time series of the electronic output data from the sensor 114) and can allow the adaptive controller to generate values for adaptive parameters of the second drive signal generator that account for a historical state of the timing device 110 (e.g., of the oscillator 112 and/or the adaptive controller 122).

In examples, one or more parameters of the second drive signal generator 120 can be variable in response to an instruction from the adaptive controller 122 (e.g., the adaptive controller 122 can control an electrical property of the second drive signal generator 120 to change how the second drive signal is generated from the electronic output signal). For example, the second drive signal generator can generate the second drive signal based at least in part on one or both of an adaptive excitation amplitude and an adaptive phase shift relative to the electronic output signal. While the preset phase shift and the preset excitation amplitude of the first drive signal generator 116 are governed by physical properties of the hardware of the first drive signal generator 116, the adaptive phase shift and/or the adaptive excitation amplitude of the second drive signal generator 120 can be determined based on an instruction (e.g., a signal) from the adaptive controller. In some cases, as shown, the adaptive controller 122 can receive the electronic output signal from the sensor 114 and can generate, based at least in part on the electronic drive signal, one or both of an adaptive excitation amplitude and an adaptive phase shift for the second drive signal generator, the adaptive phase shift being a calculated value for a desired phase shift relative to the electronic output signal. In examples, the adaptive controller 122 can implement one or more differential equations to generate adaptive parameters for the second drive signal generator 120. For example, the adaptive controller 122 can be performing (e.g., using numerical methods) integration or derivation of time series of the electronic input signal to generate adaptive control parameters for the second drive signal generator 120. Adaptive control parameters can thus be generated at least partially based on prior values for either or both of the electronic output signal, and the adaptive parameters themselves. For example, a process (e.g., an equation or algorithm) for generating a current value of an adaptive excitation amplitude can require, as an input, a previous value of the adaptive excitation amplitude. In some examples, the adaptive controller 122 can implement the feedback control described below in Sections III-V to adaptively control an adaptive excitation amplitude and an adaptive phase shift for the second drive signal. In other examples, an adaptive controller can vary one or more parameters of the second drive signal generator to adaptively produce the second drive signal according to any algorithm or process that can be stored at the memory 124. For example, where the oscillator is a crystal oscillator, a set of governing equations for counteraction a phase diffusion can differ from the example equations provided below, and adaptive parameters for a second drive signal of a timing device including a crystal oscillator can be determined at an adaptive controller based on the governing equations for the crystal oscillator.

In some examples, a timing device can include arrangements of components of the timing device other than illustrated in FIG. 1. For example, in FIG. 1, the first drive signal generator 116 and the second drive signal generator 120 operate in parallel, and provide separate signals to the oscillator 112 (e.g., via the driver 118). In other examples, a drive signal can be generated by arranging a first drive signal generator in series with a second drive signal generator. In examples, when a second drive signal generator is arranged downstream of a first drive signal generator (e.g., with the first drive signal provided to the second drive signal generator as an input), an adaptive controller can generate adaptive control parameters (e.g., an adaptive excitation amplitude and an adaptive phase shift) for the second drive signal generator based in part on the first drive signal output from the first drive signal generator.

In some examples, a first drive signal and a sensor output can be provided as inputs to an adaptive controller for the purpose of calculating adaptive control parameters for a second drive signal generator. In some examples, an adaptive control parameter for a second drive signal generator can be a function preset excitation amplitude and a preset phase shift of a first drive signal generator (e.g., as illustrated, for example, in equations (6) shown below). In some examples, then, where an adaptive controller is not in communication with a first drive signal generator (e.g., the adaptive controller 122 shown in FIG. 1 does not receive the first drive signal from the first drive signal generator), values for the preset excitation amplitude and the preset phase shift for the first drive signal generator have to be hard coded onto the adaptive controller (e.g., stored in the memory 124). However, where an adaptive controller receives both a sensor output indicative of the oscillations of an oscillator, and a first drive signal from a first drive signal generator, the adaptive controller can calculate the values for the preset excitation amplitude and the preset phase shift from the first drive signal, and can advantageously reduce or eliminate the need to hard-code values into the adaptive controller.

### III. Mathematical Model

A typical oscillator used for timing purposes (e.g., the oscillator 112 shown in FIG. 1) consists of a vibrating element and an electronic feedback loop that ensures that energy dissipated by the vibrating element is balanced out on average by energy provided through the electronics. A common form of electronic feedback is through a phase-locked loop which drives the vibrating element synchronously with its vibrations with some preset excitation amplitude and excitation phase shift.

A mathematical model that captures this behavior is described by a differential equation of the form shown in equation (1) below

$$\ddot{x} + 2 Γ \dot{x} + {ω}^{2} x + γ {x}^{3} = S cos ( ω t + ϕ + Δ ) \qquad ( 1 )$$

Here, x, \dot{x}, and \ddot{x} are lumped variables that describe the displacement, velocity, and acceleration of the vibrating element. The parameters Γ, ω, and γ describe physical properties of the vibrating element (e.g., an oscillator) and its environment. The quantities S and Δ describe the preset excitation amplitude and excitation phase shift of the phase-locked loop (e.g., the preset excitation amplitude and the preset phase shift of the first drive signal generator 116). Finally, for small values of Γ, γ, and S, the variable ϕ is obtained from the dominant form of the steady-state response of the vibrating element

$$x = a cos ( ω t + ϕ ) \qquad ( 2 )$$

Here, ϕ and α describe quantities that vary on a time scale that is much slower than the lowest-order approximation 2πω⁻¹ of the period of vibration.

Using an analytical method known as the method of averaging, it is possible to derive differential equations that describe the dominant variations of α and ϕ on the slow time scale. These equations are of the form given by equation (3) below, and are known as the slow-flow equations. Here, the ′ denotes differentiation with respect to the slow time scale.

$${a}^{′} = - Γ a + \frac{S sin Δ}{2 ω} , {ϕ}^{′} = \frac{3 y {a}^{3} - 4 S cos Δ}{8 ω a} \qquad ( 3 )$$

From these equations, it is possible to identify an equilibrium value of α that makes α′=0. This equilibrium value is given by

$$\hat{a} := \frac{S sin Δ}{2 ω Γ} \qquad ( 4 )$$

Independently of the initial value of a, its value converges on the slow time scale to \hat{α}. When α=\hat{α}, the corresponding value of ϕ′ is given by

$${\hat{ϕ}}^{′} := \frac{3 γ {\hat{a}}^{3} - 4 S cos Δ}{8 ω \hat{a}} \qquad ( 5 )$$

To dominant order, once α has converged to \hat{α}, the frequency of oscillation of the vibrating element then equals ω+\hat{ϕ}′.

The systems and methods for suppression noise-induced infusion can differ from conventional systems by incorporating an adaptive feedback control (e.g., in addition to the preset feedback control from the phase-locked loop described in equation (1)). In examples, the disclosure can differ from conventional systems in ways that can be described via the following modification to the governing differential equation (e.g., equation (1)).

$$\ddot{x} + 2 Γ \dot{x} + {ω}^{2} x + γ {x}^{3} = S cos ( ω t + ϕ + Δ ) - T cos ( ω t + ϕ + θ ) \qquad ( 6 )$$

Here, T and θ are the amplitude and phase shift of a second phase-locked loop (e.g., the adaptive excitation amplitude and adaptive phase shift respectively of the second drive signal generator 120). In contrast to the values of S and Δ which are preset and fixed, the values of T and θ are here governed by an auxiliary set of differential equations:

$${T}^{′} = {f}_{T} ( a , T , θ , S , Δ ) , {θ}^{′} = {f}_{θ} ( a , T , θ , S , Δ ) \qquad ( 7 )$$

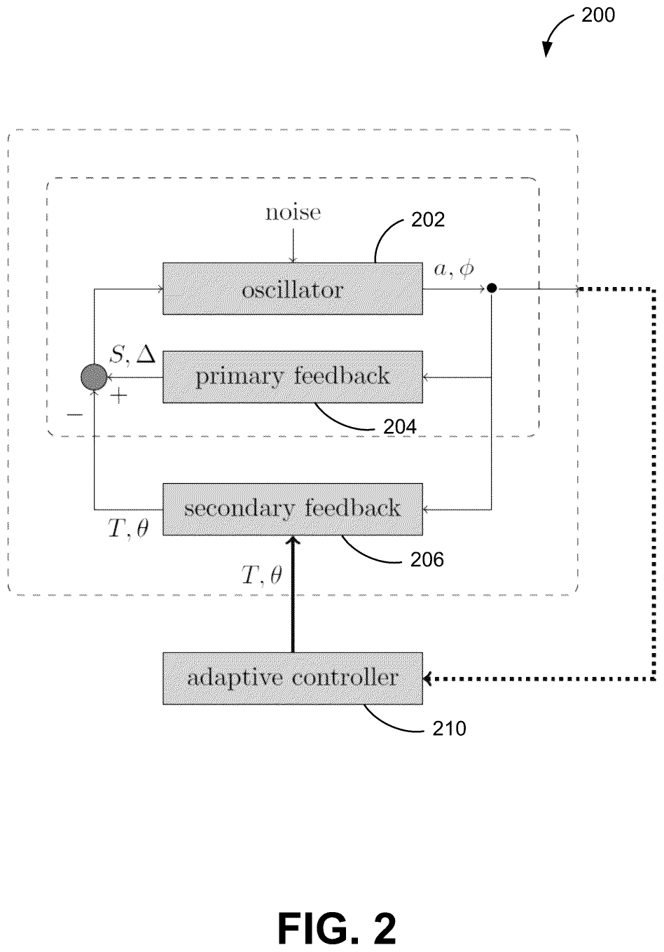

FIG. 2 illustrates an example schematic of a timing device 200 configured to implement the governing equation (5). As shown, the timing device includes a resonator 202. The resonator 202 can be similar or identical to the oscillator 112 shown in FIG. 1, and can include an oscillating element. As further shown, the resonator 202 can have a noise input that can impact an operation of the resonator 202. In some examples, the noise input can produce variations of the parameters ϕ and α on a time scale that is much slower than the lowest-order approximation 2πω⁻¹ of the period of vibration. The slow variation of the parameter ϕ can correspond to a phase diffusion of the resonator 202. Thus, without a control input to counteract a diffusion, a noise can produce a phase diffusion of the resonator 202 over time. As illustrated, an oscillator output can be provided from the resonator 202 to the primary feedback 204. The primary feedback 204 can be similar or identical to the first drive signal generator 116 shown in FIG. 1, and can generate a first drive signal based on the oscillator output.

In the illustrated example, the first drive signal can be expressed by the term Scos(ωt+θ+Δ), which is described above. Thus, the primary feedback 204 can produce an oscillating signal of the same frequency as the resonator 202, but with a different amplitude S and with a phase that is shifted by the phase shift Δ. As noted above, the amplitude S is a preset amplitude that is defined by a physical parameter of the hardware of the primary feedback 204 (e.g., defined by a physical characteristic of circuitry of the primary feedback 204). Similarly, the phase shift Δ is a preset phase shift that is defined by a physical parameter of the hardware of the primary feedback 204. The drive signal from the primary feedback 204 can be provided to the resonator 202, and can counteract a dissipation of the resonator 202 to generated a self-sustaining oscillation of the resonator 202. As noted above, the values of S and Δ are preset and fixed, and thus cannot adapt to counteract a phase diffusion represented by the slow variation of the parameter ϕ relative to its variation in the absence of noise and with α=\hat{α}.

As shown, the timing device includes a secondary feedback 206, and an adaptive controller 210. The adaptive controller 210 can receive the oscillator output, and can determine values for the adaptive amplitude T and the adaptive phase shift θ based at least in part on the oscillator output. The adaptive amplitude T and the adaptive phase shift θ can be determined (e.g., calculated) to counteract the effect of the slow variation of the parameters ϕ and α (e.g., to reduce or eliminate a phase diffusion over time). In the illustrated example, controller 210 provides the adaptive amplitude T and the adaptive phase shift θ to the secondary feedback 206. In an example, the secondary feedback 206 can comprise a phase-locked loop configured to output a second drive signal of the amplitude T and a phase shift θ relative to an input signal. Thus, the secondary feedback 206 generates a drive signal that is described by the term −Tcos(ωt+ϕ+θ) (e.g., as shown in equation (5)), and the adaptive amplitude T and adaptive phase shift θ can be varied over time to mitigate a phase diffusion, as further described below. The second drive signal can be provided to the resonator 202, and can drive the resonator 202 to counteract an effect of the noise on the resonator 202.

The functions ƒ_{T} and ƒ_{θ} implement a feedback relationship on the slow time scale that is purposefully designed to modify the behavior that results with only a single phase-locked loop. In Section IV, we show how ƒ_{T} and ƒ_{θ} may be designed in order to fully compensate for noise-induced phase diffusion which results in undesirable uncertainty in the frequency of the vibrating element.

With the addition of the second phase-locked loop, we obtain the following differential equations governing the slowly varying amplitude α and phase shift ϕ:

$${a}^{′} = - Γ a + \frac{S sin Δ - T sin θ}{2 ω} , {ϕ}^{′} = \frac{3 γ {a}^{3} - 4 S cos Δ + 4 T cos θ}{8 ω a} \qquad ( 8 )$$

In this case, α′=0 when α=\hat{α}, where

$$\hat{a} : = \frac{S sin Δ - \hat{T} sin \hat{θ}}{2 ωΓ} \qquad ( 9 )$$

Similarly, when α=\hat{α}, T′=θ′=0 for T=\hat{T} and θ=\hat{θ} where \hat{T} and \hat{θ} satisfy the equations:

$${f}_{T} ( \hat{a} , \hat{T} , \hat{θ} , S , Δ ) = 0 , {f}_{θ} ( \hat{a} , \hat{T} , \hat{θ} , S , Δ ) = 0 \qquad ( 10 )$$

Finally, when α=\hat{α}, T=\hat{T}, and θ=\hat{θ}, the corresponding value of ϕ′ equals:

$${\hat{ϕ}}^{′} := \frac{3 γ {\hat{a}}^{3} - 4 S cos Δ + 4 \hat{T} cos \hat{θ}}{8 ω \hat{a}} \qquad ( 11 )$$

By appropriate design of ƒ_{T} and θ_{θ}, it follows that α, T, and θ converge to \hat{α}, \hat{T}, and \hat{θ}. To dominant order, the frequency of oscillation of the vibrating element then equals ω+\hat{ϕ}′.

Thus, the present disclosure provides a method for modifying the dynamics of the oscillator through the introduction of a second phase-locked loop with amplitude T and phase shift θ governed on the slow time scale by feedback laws of the form T′=f_{T}(a, T, θ, S, Δ) and θ′=f_{θ}(a, T, θ, S, Δ). Purposeful modifications to these values may dramatically change the behavior of the oscillator in ways that are advantageous to its use (e.g., in ways that reduce or eliminate phase diffusion).

### IV. Noise-induced Diffusion

One application of the presently described methods and systems relates to the cancellation, to dominant order, of noise-induced diffusion of the phase shift ϕ.

In the absence of the second phase-locked loop (i.e., with T=0), a mathematical model of the influence of noise on the slowly varying amplitude α and phase shift ϕ is given by the stochastic differential equations:

$$da = ( - Γ a + \frac{S sin Δ}{2 ω} ) d τ + \sqrt{{D}_{a}} {dW}_{a} , d ϕ = \frac{3 γ {a}^{3} - 4 S cos Δ}{8 ω a} d τ + \sqrt{{D}_{ϕ}} {dW}_{ϕ} \qquad ( 12 )$$

Here, 96 denotes the slow time scale, dW_{α} and dW_{ϕ} are independent standard Brownian motions, and d\sqrt{D_{α}} and \sqrt{D_{ϕ}} are the corresponding noise amplitudes. Since we are concerned with the effects of noise on the dynamics near the steady-state values α=\hat{α} and ϕ=\hat{ϕ}′τ, we can linearize these equations to obtain:

$$d δ a = - Γδ a d τ + \sqrt{{D}_{a}} {dW}_{a} , d δ ϕ = \frac{3 γ {\hat{a}}^{3} + 2 S cos Δ}{4 ω {\hat{a}}^{2}} δ a d τ + \sqrt{{D}_{ϕ}} {dW}_{ϕ} \qquad ( 13 )$$

Here, δα=α−\hat{α} and δϕ=ϕ−\hat{ϕ}′τ. Standard tools of analysis may be used to show that the magnitude of the noise-induced phase diffusion is given by the expression:

$${( \frac{3 γ {\hat{a}}^{3} + 2 S cos Δ}{4 ω {\hat{a}}^{2} Γ} )}^{2} {D}_{a} + {D}_{ϕ} \qquad ( 14 )$$

The numerical value of this quantity is determined by the values of the parameters γ, ω, and Γ, the excitation amplitude S and excitation phase shift ϕ, and the noise intensities D_{α} and D_{ϕ}. The purposeful modification of the behavior that we seek is to achieve zero noise-induced phase diffusion to dominant order.

With the addition of the second phase-locked loop, a mathematical model of the influence of noise on the slowly varying amplitude α and phase shift ϕ is given by the stochastic differential equations:

$$da = ( - Γ a + \frac{S sin Δ - T sin θ}{2 ω} ) d τ + \sqrt{{D}_{a}} {dW}_{a} , d ϕ = \frac{3 γ {a}^{3} - 4 S cos Δ + 4 T cos θ}{8 ω a} d τ + \sqrt{{D}_{ϕ}} {dW}_{ϕ} \qquad ( 15 )$$

As before, we assume that T is governed by a deterministic differential equation:

$$dT = {f}_{T} ( a , T , θ , S , Δ ) d τ \qquad ( 16 )$$

We introduce the variable ψ such that:

$${ψ}^{′} = {f}_{θ} ( a , T , θ , S , Δ ) - k \frac{3 γ {a}^{3} - 4 S cos Δ + 4 T cos θ}{8 ω a} \qquad ( 17 )$$

for some to-be-determined constant k and define θ as the sum ψ+kϕ, such that:

$$d θ = {f}_{θ} ( a , T , θ , S , Δ ) d τ + k \sqrt{{D}_{ϕ}} {dW}_{ϕ} \qquad ( 18 )$$

Linearization about α=\hat{α}, T=\hat{T}, θ=\hat{θ}, and ϕ=\hat{ϕ}′τ yields:

$$d δ a = ( - Γδ a - \frac{sin \hat{θ}}{2 ω} δ T - \frac{\hat{T} cos \hat{θ}}{2 ω} δθ ) d τ + \sqrt{{D}_{a}} {dW}_{a} , \qquad ( 19 )$$

$$d δ T = ( {\hat{f}}_{T , a} δ a + {\hat{f}}_{T , T} δ T + {\hat{f}}_{T , θ} δθ ) d τ ,$$

$$d δ θ = ( {\hat{f}}_{θ , a} δ a + {\hat{f}}_{θ , T} δ T + {\hat{f}}_{θ , θ} δθ ) d τ + k \sqrt{{D}_{ϕ}} {dW}_{ϕ} ,$$

$$d δ ϕ = ( \frac{3 γ {\hat{a}}^{3} + 2 S cos Δ - 2 \hat{T} cos \hat{θ}}{4 ω {\hat{a}}^{2}} δ a + \frac{cos \hat{θ}}{2 ω \hat{a}} δ T - \frac{\hat{T} sin \hat{θ}}{2 ω \hat{a}} δ θ ) d τ + \sqrt{{D}_{ϕ}} {dW}_{ϕ}$$

Here, \hat{ƒ}_{*,*}=ƒ_{*,*}(\hat{α}₁, \hat{T}, \hat{θ}, S, Δ). Standard tools of analysis may be used to show that the magnitude of the noise-induced phase diffusion is now given by the expression:

$${( \frac{{n}_{a}}{{d}_{a}} )}^{2} {D}_{a} + {( \frac{{n}_{ϕ}}{{d}_{ϕ}} )}^{2} {D}_{ϕ} \qquad ( 20 )$$

$$where$$

$${n}_{a} = ( 3 {\hat{a}}^{3} γ + 2 S cos Δ - 2 \hat{T} cos \hat{θ} ) ( {\hat{f}}_{T , θ} {\hat{f}}_{θ , T} - {\hat{f}}_{T , T} {\hat{f}}_{θ , θ} ) + 2 \hat{a} cos \hat{θ} ( {\hat{f}}_{T , a} {\hat{f}}_{θ , θ} - {\hat{f}}_{T , θ} {\hat{f}}_{θ , a} ) + 2 \hat{a} \hat{T} sin \hat{θ} ( {\hat{f}}_{T , a} {\hat{f}}_{θ , T} - {\hat{f}}_{T , T} {\hat{f}}_{θ , a} ) \qquad ( 21 )$$

$${n}_{ϕ} = 8 {\hat{a}}^{2} {ω}^{2} Γ ( {\hat{f}}_{T , θ} {\hat{f}}_{θ , T} - {\hat{f}}_{T , T} {\hat{f}}_{θ , θ} ) + 4 {\hat{a}}^{2} ω sin \hat{θ} ( {\hat{f}}_{T , a} {\hat{f}}_{θ , θ} - {\hat{f}}_{T , θ} {\hat{f}}_{θ , a} ) - 4 {\hat{a}}^{2} ω \hat{T} cos \hat{θ} ( {\hat{f}}_{T , a} {\hat{f}}_{θ , T} - {\hat{f}}_{T , T} {\hat{f}}_{θ , a} ) + k ( ( sin \hat{θ} {\hat{f}}_{T , θ} - \hat{T} cos \hat{θ} {\hat{f}}_{T , T} ) ( 3 {\hat{a}}^{3} γ + 2 S cos Δ - 2 \hat{T} cos \hat{θ} ) + 2 \hat{a} \hat{T} {\hat{f}}_{T , a} - 4 \hat{a} Γωcos \hat{θ} {\hat{f}}_{T , θ} - 4 \hat{a} \hat{T} Γ ω sin \hat{θ} {\hat{f}}_{T , T} )$$

and d_{α}, d_{ϕ}≠0. We note that n_{α}=0 if ƒ_{T} and ƒ_{θ} are designed to be independent of θ and if \hat{θ}=0. The latter implies that \hat{α}=SsinΔ/2ωθ, just like in the case with the single phase-locked loop. Similarly, unless the coefficient of k is 0, n_{ϕ} is linear in k and n_{ϕ}=0 for a unique value of k. Choosing ƒ_{T}, ƒ_{θ}, and k accordingly results in 0 magnitude of the noise-induced phase diffusion to dominant order of analysis.

Thus, the present disclosure can provide a method for defining k and choosing ƒ_{T} and ƒ_{θ} such that the noise-induced phase diffusion equals 0 to dominant order of analysis. Except for very special circumstances, such a choice is always possible.

As an example, let \hat{θ}=0 and suppose that ƒ_{T} and ƒ_{θ} are chosen to be linear in α and T and of the form

$${f}_{T} = {ξ}_{T} + {ξ}_{T , a} a + {ξ}_{T , T} T , {f}_{θ} = {ξ}_{θ} + {ξ}_{θ , a} a + {ξ}_{θ , T} T \qquad ( 22 )$$

$$where$$

$${ξ}_{T , a} {ξ}_{θ , T} - {ξ}_{T , T} {ξ}_{θ , a} , {ξ}_{T , T} ( 3 {\hat{a}}^{3} γ + 2 S cos Δ - 2 \hat{T} ) - 2 \hat{a} {ξ}_{T , a} \neq 0 \qquad ( 23 )$$

It immediately follows that n_{α}=0. Furthermore, let

$$k = \frac{4 {\hat{a}}^{2} ω ( {ξ}_{T , T} {ξ}_{θ , a} - {ξ}_{T , a} {ξ}_{θ , T} )}{{ξ}_{T , T} ( 3 {\hat{a}}^{3} γ + 2 S cos Δ - 2 \hat{T} ) - 2 \hat{a} {ξ}_{T , a}} \qquad ( 24 )$$

It then follows that n_{ϕ}=0.

### V. Numerical Results for Feedback Design

As an example, suppose that Γ=γ=ω=S=\hat{T}=1 and define

$${f}_{T} = a - \hat{a} + \hat{T} - T , {f}_{θ} = a - \hat{a} + 2 ( T - \hat{T} ) \qquad ( 25 )$$

It follows that the value of k for which n_{ϕ}=0 equals −4.8.

To validate this prediction, we choose D_{α}=D_{ϕ}=10⁻⁴ and perform 100 independent numerical simulations of the linearized equations using an Euler-Maruyama integrator with Δt=10⁻³ and, in each case, compute the value of δϕ after 2×10⁶ time steps. Finally, we compute the statistical variance of these values, divide by 2000 and compare against the predicted magnitude of the noise-induced phase diffusion.

In the case of the single feedback loop, the predicted magnitude equals 1.1×10⁻⁴ Numerical simulation yields the value 1.3×10⁻⁴ in close agreement with the prediction. Similarly, with the addition of the second feedback loop but with k=0, the predicted magnitude equals 1.0×10⁻⁴ while the numerical simulation yields the value 8.0×10⁻⁵. Finally, with the addition of the second feedback loop and k=−4.8, the predicted magnitude equals 0 while the numerical simulation yields the value 3.47×10⁻⁷. This three-orders-of-magnitude reduction from the value without the second feedback loop is consistent with the predicted magnitude, given that the numerical technique is only approximately accurate in simulating the stochastic differential equations.

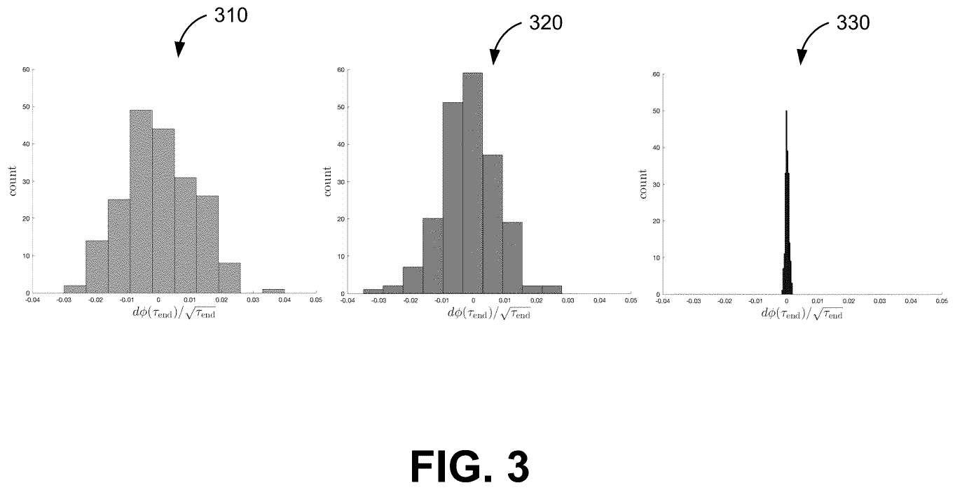

Thus, the disclosed systems and methods allow for design of adaptive feedback controls that can reduce a noise-induced phase diffusion of an oscillator for a timing device. In this regard, FIG. 3 illustrates the results of the numerical simulations for the different designs of feedback control, showing an impact of the respective feedback designs on the phase diffusion of the system.

Panels 310, 320, and 330 of FIG. 3 are bar charts showing the distribution of the deviation dϕ(τ_{end})=δϕ(τ_{end})−<δϕ(τ_{end})> of the phase from its ensemble average at τ_{end}=2000 (i.e., after 2×10⁶ time-steps), normalized by the square root of τ_{end}. As shown, a width of the phase distribution is largest in the absence of the second feedback loop (310), intermediate in the presence of the second feedback loop but with k=0 (320), and smallest in the presence of the second feedback loop but with k=−4.8 (330), further illustrating an efficacy of a secondary loop with an optimal choice of k for mitigating a phase diffusion, relative to conventional systems with only a primary feedback loop.

### VI. Example Methods

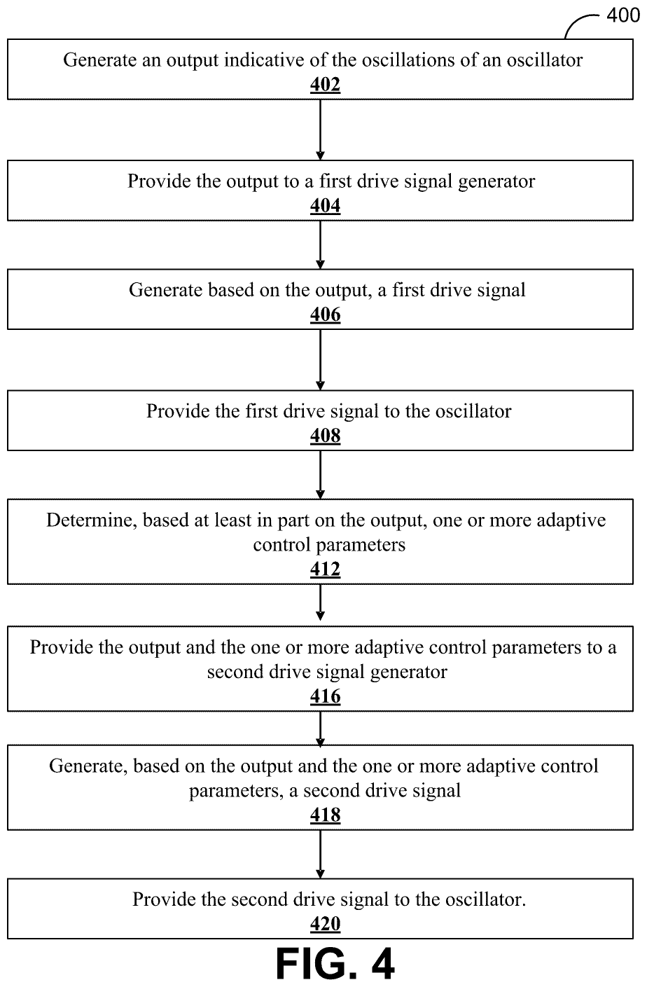

FIG. 4 is a flow chart illustrating an example embodiment of a process 400 according to the present disclosure. The process 400 illustrated by FIG. 4 may be carried out by a timing device, such as the timing device 110 shown in FIG. 1. However, the process 400 can be carried out by other types of devices or device subsystems. For example, components of the timing device 110 can be software defined, and the respective operations of the components can be performed in a software of one or more computing devices.

The process 400 of FIG. 4 may be simplified by the removal of any one or more of the features shown therein. Further, these embodiments may be combined with features, aspects, and/or implementations of any of the previous figures or otherwise described herein.

At block 402, an output can be generated indicative of the oscillations of an oscillator. In an example, the output can be an electrical output signal with a periodicity (e.g., a frequency) that is indicative (e.g., representative) of oscillations of an oscillation. The output can be a continuous signal and can comprise a time series of voltage values corresponding to the oscillations of the oscillator. In various examples, the output can be provided by a sensor that senses a movement of the oscillator and translates that movement to voltage values. In some examples, an oscillation (e.g., a vibration) of the oscillator can produce voltage changes in an electrical element (e.g., a conductive plate) in proximity to the oscillator, and the output can include the voltage change values. In examples, the output can be the electrical output signal generated at sensor 114 and described in FIG. 1.

At block 404, the output (e.g., the output signal indicative of the oscillations of an oscillator) can be provided to a first drive signal generator. The first drive signal generator can define a first operation for generating a first drive signal based on the output. For example, the first drive signal generator can be configured to output a signal having a preset amplitude and a preset phase shift relative to a signal input to the first drive signal generator. The preset amplitude and the preset phase shift can be hard-coded into the first drive signal generator, and need not vary based on a time or time-varying parameter of the output.

At block 406, a first drive signal can be generated based on the output. The first drive signal can be a signal with similar properties as the output. For example, the first drive signal can have a similar (e.g., identical) frequency as the output. In examples, the first drive signal has a preset amplitude and a preset phase shift relative to the output. The preset amplitude and the preset phase shift can be based on physical parameters of the first drive signal generator. Thus, for a given signal (e.g., the output) provided to the first drive signal generator, neither of the excitation amplitude or the phase shift of the first drive signal varies based on a parameter of the output, or based on time or other variables (e.g., the excitation amplitude and phase shift of the first drive signal generator are constant).

At block 408, the first drive signal can be provided to the oscillator. The first drive signal drives the oscillator synchronously with the frequency of the oscillator, and thereby provides a self-sustaining oscillation of the oscillator. In some examples, the first drive signal is provided as an analog signal. In some examples, the first drive signal can be a stepwise function, or a box wave, for example. Providing the first drive signal to the oscillator can comprise providing the voltage of the first drive signal directly to the oscillator (e.g., via electrodes). In other examples, drive elements (e.g., driver 118 shown in FIG. 1) can translate the voltage values of the first drive signal to a mechanical drive input for the oscillator to drive an oscillation of the oscillator.

At block 412, the process 400 can include determining one or more adaptive control parameters for a second drive signal generator, based at least in part on the output. For example, the second drive signal controller can be configured to generate a second drive signal having an amplitude and a phase shift relative to the output. Determining the one or more adaptive control parameters can include determining, in real time, adaptive values for an amplitude and a phase shift for the second drive signal. The one or more adaptive control parameters (e.g., the adaptive phase shift and/or adaptive amplitude) can be determined based on the differential equations described above in the “Mathematical Model” section. For example, an adaptive controller can have stored thereon instructions for implementing the differential equations recited in the “Mathematical Model” section to calculate, based at least in part on the output, values of the one or more adaptive control parameters. In some examples, determining a value of an adaptive control parameter can include performing a calculation using a prior value of the adaptive control parameter and the output. In other examples, adaptive control parameters can be generated according to other methods. For example, in some cases, an adaptive controller can generate adaptive control parameters for controlling a frequency according to some examples.

At block 416, the process 400 can include providing the output and the one or more adaptive control parameters to a second drive signal generator. In an example, the one or more adaptive control parameters can control an electrical property of the second drive signal generator. For example, the second drive signal generator can include variable resistors with resistance values that can be varied in response to a variation of the adaptive control parameters. In some examples, as noted above, the one or more adaptive control parameters can include an adaptive excitation amplitude and an adaptive phase shift.

At block 418, the process can include generating a second drive signal based on the output and the one or more adaptive control parameters. For example, variable elements of the second drive signal generator (e.g., variable resistors) can be adjusted based on the adaptive excitation amplitude and adaptive phase shift determined by the adaptive controller to achieve a desired amplitude of a second drive signal and phase shift of the second drive signal relative to the output.

At block 420, the process can include providing the second drive signal to the oscillator. The second drive signal can vary over a slow time scale to counteract a slow phase diffusion of the oscillator.

### VII. Conclusion

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step or block that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer readable medium such as a storage device including RAM, a disk drive, a solid state drive, or another storage medium.

The computer readable medium can also include non-transitory computer readable media such as computer readable media that store data for short periods of time like register memory and processor cache. The computer readable media can further include non-transitory computer readable media that store program code and/or data for longer periods of time. Thus, the computer readable media may include secondary or persistent long-term storage, like ROM, optical or magnetic disks, solid state drives, or compact disc read only memory (CD-ROM), for example. The computer readable media can also be any other volatile or non-volatile storage systems. A computer readable medium can be considered a computer readable storage medium, for example, or a tangible storage device.

Moreover, a step or block that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A system comprising:
a sensor configured to generate a sensor output indicative of oscillations of an oscillator;
a first drive signal generator, configured to receive the sensor output, and generate, based on the sensor output, a first drive signal, wherein the first drive signal generator provides the first drive signal to the oscillator;
an adaptive controller configured to receive the sensor output, and determine, based at least in part on the sensor output, one or more adaptive control parameters; and
a second drive signal generator configured to receive the sensor output and the adaptive control parameters, and generate, based on the sensor output and the adaptive control parameters, a second drive signal, wherein the second drive signal generator provides the second drive signal to the oscillator.

2. The system of claim 1, wherein the adaptive controller is further configured to:
generate a first value of an adaptive control parameter at a first time; and
generate a second value for the adaptive control parameter at a second time, wherein the second value is generated based at least in part on the first value.

3. The system of claim 1, wherein the oscillator comprises a microelectromechanical system (MEMS) oscillator.

4. The system of claim 1, wherein the first drive signal generator comprises a first hardware component, wherein the first drive signal is generated based at least in part on a preset excitation amplitude, wherein the preset excitation amplitude is based on a first physical parameter of the first hardware component.

5. The system of claim 4, wherein the first drive signal is based at least in part on a preset phase shift, wherein the preset phase shift is indicative of a phase difference between the sensor output and the first drive signal, wherein the preset phase shift is based on a second physical parameter of the first hardware component.

6. The system of claim 1, wherein the one or more adaptive control parameters include an adaptive excitation amplitude, wherein the second drive signal is based at least in part on the adaptive excitation amplitude.

7. The system of claim 1, wherein the one or more adaptive control parameters include an adaptive phase shift, the adaptive phase shift at least partially defining a phase difference between the second drive signal and the sensor output.

8. The system of claim 1, wherein the first drive signal is described by a first oscillatory function with preset excitation amplitude S and preset phase shift Δ, wherein Δ defines a phase difference between the first drive signal and the sensor output, and the second drive signal is described by a second oscillatory function with adaptive excitation amplitude T and adaptive phase shift θ, wherein θ defines a phase difference between the second drive signal and the sensor output.

9. The system of claim 8, wherein the first oscillatory function is described by the expression Scos(ωt+ϕ+Δ) and the second oscillatory function is described by expression Tcos(ωt+ϕ+θ) where:
ω is representative of a physical parameter of the oscillator.

10. The system of claim 9, wherein an average change in ϕ over a time scale 2πω\hat{ }(−1) is less than 1.

11. The system of claim 1, wherein the first drive signal generator comprises a first phase-locked loop, and wherein the second drive signal generator comprises a second phase-locked loop.

12. The system of claim 1, wherein the adaptive controller comprises a microcontroller.

13. The system of claim 9, wherein the adaptive controller is configured to determine the adaptive excitation amplitude T based at least in part on the preset excitation amplitude S and a preset constant.

14. A method of reducing a noise-induced phase diffusion for an oscillator, the method comprising:
generating an output indicative of the oscillations of an oscillator;
providing the output to a first drive signal generator,
generating a first drive signal at the first drive signal generator, based at least in part on the output, a preset excitation amplitude, and a preset phase difference;
providing the first drive signal to the oscillator;
providing the output to an adaptive controller;
generating, at the adaptive controller, an adaptive excitation amplitude and an adaptive phase difference, the adaptive excitation amplitude and the adaptive phase difference being generated based at least in part on the output;
providing the adaptive excitation amplitude and the adaptive phase difference to a second drive signal generator;
generating a second drive signal at the second drive signal generator, based at least in part on the output, the adaptive excitation amplitude, and the adaptive phase difference; and
providing the second drive signal to the oscillator.

15. The method of claim 14, wherein the oscillator is a microelectromechanical system (MEMS) oscillator.

16. A method of reducing a noise-induced phase diffusion for an oscillator, the method comprising:
generating, at a sensor, an output indicative of the oscillations of an oscillator;
providing the output to a first drive signal generator;
generating at the first drive signal generator, based on the sensor output, a first drive signal;
providing the first drive signal to the oscillator to drive an oscillation of the oscillator;
providing the output to an adaptive controller;
determining, at the adaptive controller, based at least in part on the sensor output, one or more adaptive control parameters;
providing the output and the one or more adaptive control parameters to a second drive signal generator;
generating, at the second drive signal generator, based on the output and the one or more adaptive control parameter, a second drive signal; and
providing the second drive signal to the oscillator to drive an oscillation of the oscillator.

17. The method of claim 16, wherein the first drive signal generator comprises a first hardware component, wherein the first drive signal is generated based at least in part on a preset excitation amplitude, wherein the preset excitation amplitude is based on a first physical parameter of the first hardware component.

18. The method of claim 17, wherein the first drive signal is based at least in part on a preset phase shift, wherein the preset phase shift is indicative of a phase difference between the output and the first drive signal, wherein the preset phase shift is based on a second physical parameter of the first hardware component.

19. The method of claim 16, wherein the one or more adaptive control parameters include an adaptive excitation amplitude, wherein the second drive signal is based at least in part on the adaptive excitation amplitude.

20. The method of claim 16, wherein the one or more adaptive control parameters include an adaptive phase shift, the adaptive phase shift at least partially defining a phase difference between the second drive signal and the output.
